(19) United States
(12) Patent Application Publication
(10) Pub. No.: US 2010/0151693 A1
(43) Pub. Date: Jun. 17, 2010

(54) METHOD FOR MANUFACTURING SEMICONDUCTOR DEVICE COMPRISING MUTIOXIDE

(76) Inventor: Takashi SHIMIZU, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/625,807

(22) Filed: Nov. 25, 2009

(30) Foreign Application Priority Data
Dec. 16, 2008 (JP) 2008-320104

(51) Int. Cl. H01L 21/31

(52) U.S. Cl. 438/761; 257/E21.24

(57) ABSTRACT

A semiconductor device comprises a first region including a first semiconductor element and a second region including a second semiconductor element different from the first semiconductor element. A silicon germanium film is formed on a surface of a semiconductor substrate in the first region and the second region. The surface of the silicon germanium film at least in the first region is nitrided. A first insulating film mainly includes silicon and oxygen is formed, on the silicon germanium film nitrided at least in the first region in the first region and the second region. The first insulating film in the second region is removed. A second insulating film mainly includes metal and oxygen is formed, on the nitrided silicon germanium film in the second region.

### CROSS-REFERENCE TO RELATED APPLICATIONS

This application is based upon and claims the benefit of priority from prior Japanese Patent Application No. 2008-320104, filed Dec. 16, 2008, the entire contents of which are incorporated herein by reference.

### BACKGROUND OF THE INVENTION

1. Field of the Invention

The present invention relates to a method for manufacturing a semiconductor device comprising a plurality of semiconductor elements among which the film thickness of a gate insulating film varies.

2. Description of the Related Art

To improve hole mobility by applying compressive stress to a channel region and to control the threshold voltage of a stacked MOSFET with a metal gate electrode and a high-dielectric-constant insulating film (high-k film) are problems to be solved for p-type FETs in LSIs. Thus, a technique has been proposed which subjects forming a silicon germanium film (SiGe film) in a channel region in a p-type FET by selective epitaxial growth.

In general, this SiGe channel technique is applied to a generation of LSIs which uses a high-dielectric-constant insulating film as a gate insulating film in a transistor. The same LSI of this generation comprises several types of transistors among which the film thickness of a gate insulating film (oxide film) varies (multioxide). In transistors comprising thicker gate insulating films, a silicon oxide film or a stacked film of a silicon oxide film and a high-k film is used as the gate insulating film. Thus, in the transistors comprising thicker gate insulating films, the oxide film is formed on the SiGe film.

Thermal oxidation has commonly been used to form a gate oxide film. However, when the thermal oxidation is used, silicon (Si) and germanium (Ge) are simultaneously introduced into the oxide film. Thus, interface characteristics and reliability may be degraded.

To avoid this, a deposition method such as CVD is used instead of the thermal oxidation to form a silicon oxide film. However, even with the deposition method, an oxidant reacts with the SiGe film during the initial phase of the deposition. Thus, Ge diffuses from the SiGe film being deposited and is introduced into the formed oxide film. As a result, the interface characteristics and reliability may be degraded.

To solve this problem, the surface of an SiGe film is pre-nitrided to form a barrier film composed of nitrogen, according to Jpn. Pat. Appln. KOKAI Publication No. 5-218014. This enables the possible diffusion of Ge to the oxide film to be inhibited.

On the other hand, thinner transistors use a high-k film as a gate insulating film. In this case, when only the high-k film is used as a gate insulating film, an interface state present at the interface between the SiGe film and the high-k film may degrade electrical characteristics. As a result, the interface characteristics and reliability may be degraded.

Thus, in the method (multioxide process) for manufacturing a semiconductor device comprising transistors of different film thickness types as described above, it is difficult to simultaneously inhibit the possible degradation of the interface characteristics and reliability in transistors of different film thickness types using a small number of steps.

### BRIEF SUMMARY OF THE INVENTION

According to a first aspect of the invention, there is provided a method for manufacturing a semiconductor device comprising a first region including a first semiconductor element and a second region including a second semiconductor element different from the first semiconductor element, the method comprising: forming a silicon germanium film on a surface of a semiconductor substrate in the first region and the second region; nitriding the surface of the silicon germanium film at least in the first region; forming a first insulating film mainly comprising silicon and oxygen, on the silicon germanium film nitrided at least in the first region in the first region and the second region; removing the first insulating film in the second region; and forming a second insulating film mainly comprising metal and oxygen, on the nitrided silicon germanium film in the second region.

According to a second aspect of the invention, there is provided a method for manufacturing a semiconductor device comprising a first region including a first semiconductor element and a second region including a second semiconductor element different from the first semiconductor element, the method comprising: forming a silicon germanium film on a surface of a semiconductor substrate in the first region and the second region; forming a silicon film on the silicon germanium film in the first region and the second region; nitriding a surface of the silicon film in the first region and the second region; forming a first insulating film mainly comprising silicon and oxygen, on the nitrided silicon film in the first region and the second region; removing the first insulating film in the second region; and forming a second insulating film mainly comprising metal and oxygen, on the nitrided silicon film in the second region.

### BRIEF DESCRIPTION OF THE SEVERAL VIEWS OF THE DRAWING

FIGS. 1 to 6 are sectional views showing a process of manufacturing a semiconductor device according to a first embodiment of the present invention; and

FIGS. 7 to 12 are sectional views showing a process of manufacturing a semiconductor device according to a second embodiment of the present invention.

### DETAILED DESCRIPTION OF THE INVENTION

Embodiments of the present invention will be described below with reference to the drawings. In the drawings, the same components are denoted by the same reference numerals.

### First Embodiment

A first embodiment is an example of a semiconductor device comprising a pMOSFET divided into two film thickness regions including a thick-film region and a thin-film region according to the thickness of a gate insulating film, wherein the surface of a silicon germanium film (SiGe film) is nitrided to form a gate insulating film on the SiGe film.

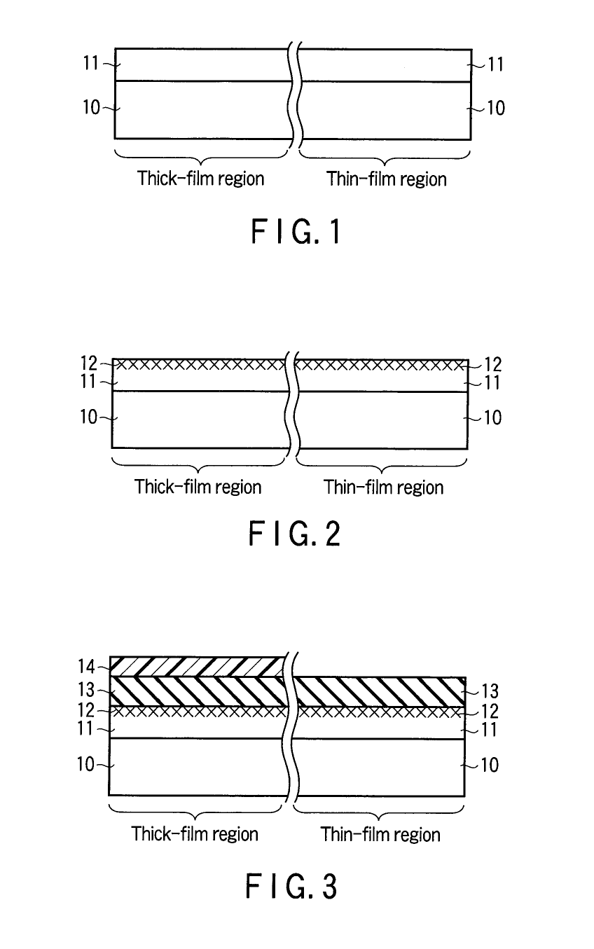

FIGS. 1 to 6 are sectional views of a process of manufacturing a semiconductor device according to a first embodiment of the present invention. The process of manufacturing the semiconductor device according to the embodiment of the present invention will be described below.

First, as shown in FIG. 1, an SiGe film 11 is formed on the surface of a silicon substrate 10 in a thick-film region and a thin-film region.

Then, as shown in FIG. 2, the surface of the SiGe film 11 in the thick- and thin-film regions is nitrided. Thus, a film containing nitrogen (the film is hereinafter referred to as an SiGe nitrogen-containing film 12) is formed on the surface of the SiGe film 11 in the thick- and thin-film regions. A method for the nitridation is desirably plasma nitridation enabling the front surface of the SiGe film 11. However, the method is not limited to this but may be thermal nitridation using gaseous NH₃, NO, N₂O, or the like.

Furthermore, in the nitridation process, nitridation conditions are optimized such that the amount of nitrogen in the SiGe nitrogen-containing film 12 is, for example, 1×10¹⁴ atoms/cm² in a film thickness of 1 nm. Then, Ge in the SiGe film 11 can be inhibited from diffusing into a silicon oxide film 13 to be formed later. In the nitridation process, the SiGe nitrogen-containing film 12 may contain oxygen. However, also in this case, the above-described effects can be exerted.

The above-described steps are similar for both the thick-film region and the thin-film region.

Then, as shown in FIG. 3, a silicon oxide film 13 is formed on the SiGe nitrogen-containing film 12 in the thick- and thin-film regions by the chemical vapor deposition (CVD) method. Here, the silicon oxide film 13 may be formed by the atomic layer deposition (ALD) method instead of the CVD method. Furthermore, the temperature at which the silicon oxide film 13 is deposited is desirably as low as possible. The insulating film material is not limited to the silicon oxide film 13. The insulating film has only to be composed mainly of at least silicon and oxygen. An example of the insulation film composed mainly of at least silicon and oxygen is a silicon oxynitride film. Thereafter, a mask material 14 is formed on the silicon oxide film 13 in the thick-film region.

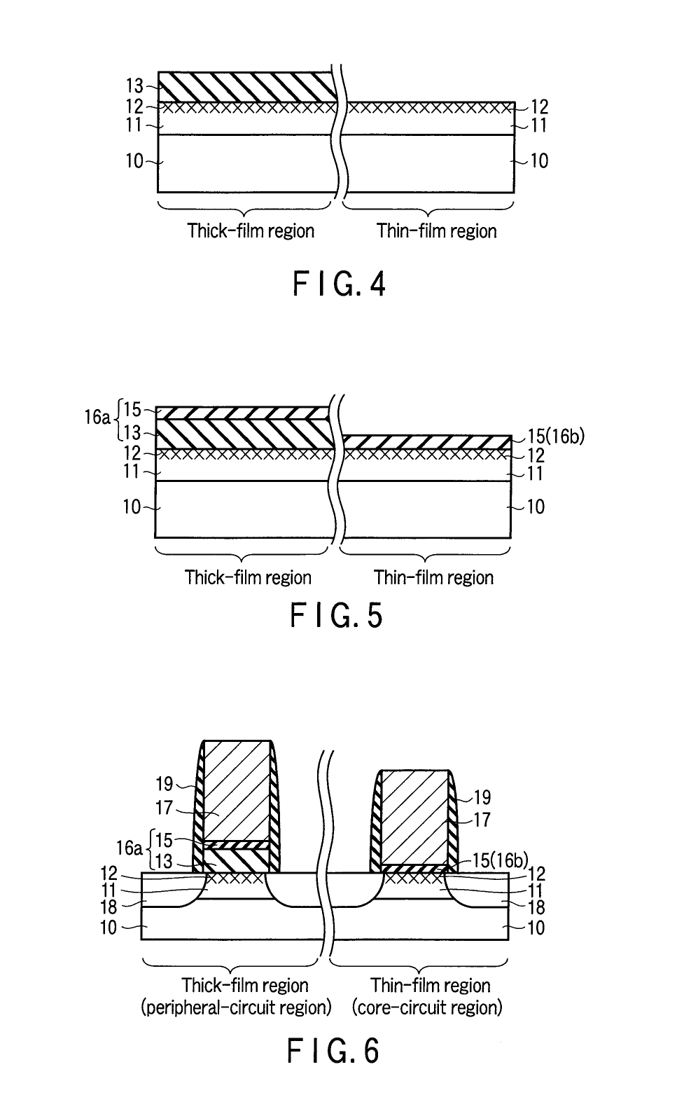

Then, as shown in FIG. 4, the silicon oxide film 13 in the thin-film region is removed by, for example, wet etching to expose the SiGe nitrogen-containing film 12 in the thin-film region. At this time, the SiGe nitrogen-containing film 12 functions as an etching stopper film. Thereafter, the mask material 14 in the thick-film region is removed.

Then, as shown in FIG. 5, a high-k film 15 is formed on the silicon oxide film 13 in the thick-film region and on the SiGe nitrogen-containing film 12 in the thin-film region. A material for the high-k film 15 has only to be composed mainly of at least metal and oxygen. Examples of the insulating film composed mainly of metal and oxygen include HfO₂, HfON, HfSiON, ZrO₂, ZrON, and ZrSiON.

As described above, a gate insulating film 16a composed of a stacked structure of the silicon oxide film 13 and the high-k film 15 is formed on the SiGe nitrogen-containing film 12 in the thick-film region. On the other hand, a gate insulating film 16b composed of the high-k film 15 is formed on the SiGe nitrogen-containing film 12 in the thin-film region.

The gate insulating film 16a in the thick-film region is not limited to the stacked structure of the silicon oxide film 13 and the high-k film 15. The gate insulating film 16a may be composed of an insulating film containing the silicon oxide film 13 or only the silicon oxide film 13. Furthermore, the gate insulating film 16b in the thin-film region is not limited to the high-k film 15 but may be composed of an insulating film containing the high-k film 15.

Thereafter, as shown in FIG. 6, a common technique is used to form a gate electrode 17 composed of, for example, polysilicon or metal, on the gate insulating films 16a and 16b in the thick- and thin-film regions. Then, the gate electrode 17 and the gate insulating films 16a and 16b are patterned. Moreover, an impurity diffusion layer 18 is formed in the silicon substrate 10 in the thick- and thin-film regions. Thereafter, sidewall insulating films 19 are formed on side surfaces of the gate insulating film 16a and gate electrode 17 in the thick-film region and on side surfaces of the gate insulating film 16b and gate electrode 17 in the thin-film region.

As described above, a transistor in the semiconductor device according to the present embodiment is completed. Here, the transistor in the thin-film region offers a high withstand voltage and is thus provided in, for example, peripheral circuit region. On the other hand, the transistor in the thin-film region is provided in, for example, a core circuit region (memory cell region).

The present embodiment is an example in which the nitridation process is executed with the SiGe film 11 exposed. However, the present embodiment is applicable to a configuration in which an oxide film is formed on the SiGe film 11. That is, the surface of the SiGe film 11 enables to be nitrided via the oxide film formed on the SiGe film 11.

Furthermore, in the present embodiment, the nitridation process is executed only once, and the SiGe nitrogen-containing film 12 is simultaneously formed in the thick-film region and in the thin-film region. However, the nitridation process may be executed a number of times in the thick-film region before the formation of the silicon oxide film 13 and in the thin-film region before the formation of the high-k film 15.

Additionally, in the present embodiment, the SiGe film 11 in the thick-film region and the SiGe film 11 in the thin-film region are both nitrided to form the SiGe nitrogen-containing film 12. However, for example, if the silicon oxide film 13 is not formed in the thin-film region, the SiGe nitrogen-containing film 12 need not be formed in the thin-film region.

According to the first embodiment, in the semiconductor device comprising the pMOSFET divided into the two film thickness regions including the thick- and thin-film regions, the surface of the SiGe film 11 formed in the channel region is nitrided to form the SiGe nitrogen-containing film 12. Thereafter, the gate insulating film 16a composed of the silicon oxide film 13 and the high-k film 15 is formed on the SiGe nitrogen-containing film 12 in the thick-film region. The gate insulating film 16b composed of the high-k film 15 is formed on the SiGe nitrogen-containing film 12 in the thin-film region.

As described above, the silicon oxide film 13 is formed on the SiGe film 11 in the thick-film region via the SiGe nitrogen-containing film 12. Thus, the SiGe nitrogen-containing film 12 effectively serves as a barrier film. This enables inhibition of the possible reaction between an oxidant and the SiGe film 11 during the initial phase of deposition of the silicon oxide film 13. This in turn reduces the diffusion of Ge from the SiGe film through the silicon oxide film 13, thus allowing the possible degradation of the interface characteristics and reliability to be inhibited.

Furthermore, the high-k film 15 is formed on the SiGe film 11 in the thin-film region via the SiGe nitrogen-containing film 12. Thus, the SiGe nitrogen-containing film 12 effectively serves as an interface layer. This allows inhibition of the possible degradation of the interface characteristics and reliability resulting from an interface state present at the interface between the SiGe film 11 and the high-k film 15.

Moreover, in the present embodiment, as described above, transistors with different film thicknesses can be simultaneously manufactured in the thick- and thin-film regions, respectively. This enables simplification of a process of manufacturing a semiconductor device which inhibits the degradation of the interface characteristics and reliability in the transistors in the respective film thickness regions.

### Second Embodiment

In the first embodiment, in the semiconductor device comprising the pMOSFET divided into the two film thickness regions, the surface of the SiGe film is nitrided to form a gate insulating film on the SiGe film. In contrast, a second embodiment is an example in which a silicon film (Si film) is formed on the SiGe film and the surface of the Si film is then nitrided. Here, the description of aspects similar to those of the first embodiment is omitted, and differences from the first embodiment will be described in detail.

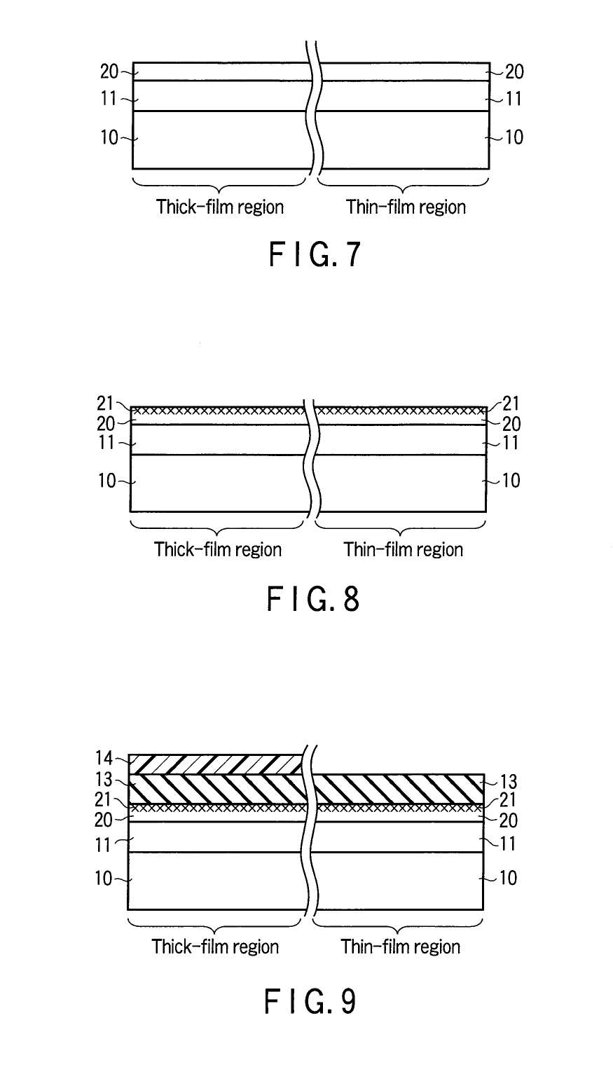

FIGS. 7 to 12 are sectional views of a process of manufacturing a semiconductor device according to the second embodiment of the present invention. The process of manufacturing the semiconductor device according to the embodiment of the present invention will be described below.

First, as shown in FIG. 7, an SiGe film 11 is formed on the surface of a silicon substrate 10 in a thick-film region and a thin-film region as is the case with the first embodiment. Thereafter, an Si film 20 is formed on the SiGe film 11 in the thick- and thin-film regions.

Then, as shown in FIG. 8, the surface of the Si film 20 in the thick- and thin-film regions is nitrided. Thus, a film containing nitrogen (hereinafter referred to as an Si nitrogen-containing film 21) is formed on the surface of the Si film 20 in the thick- and thin-film regions. A method for the nitridation is desirably plasma nitridation as is the case with the first embodiment. However, the method is not limited to this but may be thermal nitridation using gaseous NH₃, NO, N₂O, or the like.

The above-described steps are similar for both the thick-film region and the thin-film region.

Then, as shown in FIG. 9, a silicon oxide film 13 is formed on the Si nitrogen-containing film 21 in the thick- and thin-film regions by the CVD method. The insulating film is not limited to the silicon oxide film 13. The insulating film has only to be composed mainly of at least silicon and oxygen. Then, a mask material 14 is formed on the silicon oxide film 13 in the thick-film region.

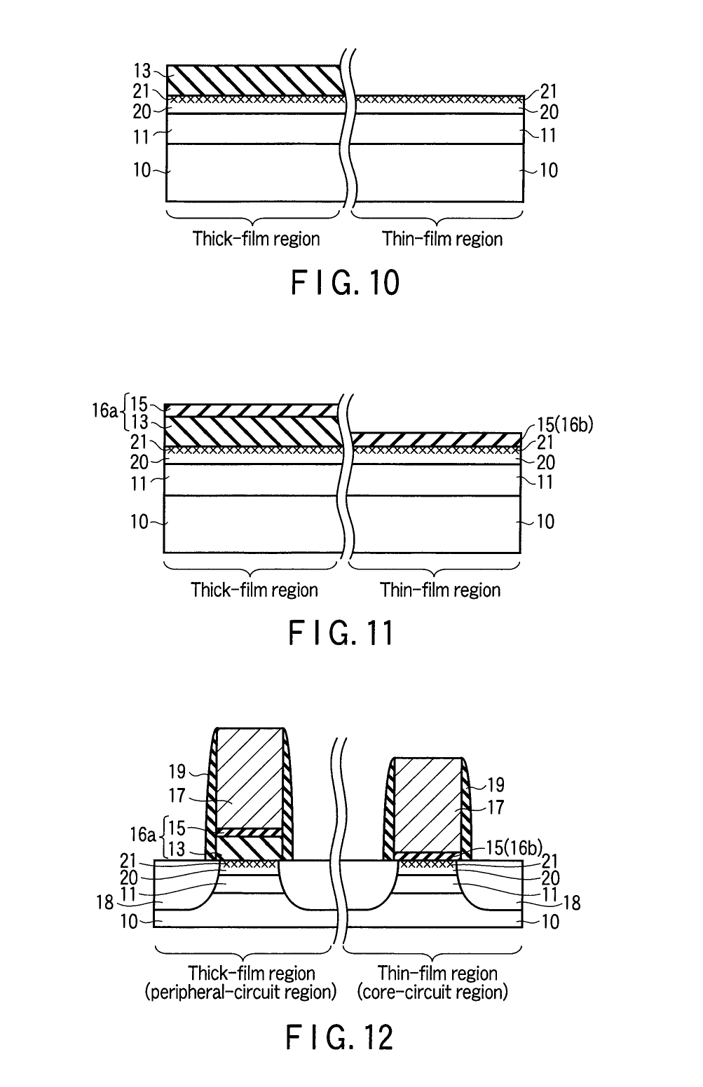

Then, as shown in FIG. 10, the silicon oxide film 13 in the thin-film region is removed by, for example, wet etching to expose the Si nitrogen-containing film 21 in the thin-film region. At this time, the Si nitrogen-containing film 21 functions as an etching stopper film. Thereafter, the mask material 14 in the thick-film region is removed.

Then, as shown in FIG. 11, a high-k film 15 is formed on the silicon oxide film 13 in the thick-film region and on the Si nitrogen-containing film 21 in the thin-film region. A material for the high-k film 15 has only to be composed mainly of at least metal and oxygen.

As described above, a gate insulating film 16a composed of a stacked structure of the silicon oxide film 13 and the high-k film 15 is formed on the Si nitrogen-containing film 21 in the thick-film region. On the other hand, a gate insulating film 16b composed of the high-k film 15 is formed on the Si nitrogen-containing film 21 in the thin-film region.

Thereafter, as shown in FIG. 12, a common technique is used to form a gate electrode 17 composed of, for example, polysilicon or metal, on the gate insulating films 16a and 16b in the thick- and thin-film regions. Then, the gate electrode 17 and the gate insulating films 16a and 16b are patterned. Moreover, an impurity diffusion layer 18 is formed in the silicon substrate 10 in the thick- and thin-film regions. Thereafter, sidewall insulating films 19 are formed on side surfaces of the gate insulating film 16a and gate electrode 17 in the thick-film region and on side surfaced of the gate insulating film 16b and gate electrode 17 in the thin-film region.

As described above, a transistor in the semiconductor device according to the present embodiment is completed.

The above-described second embodiment can exert effects similar to those of the first embodiment.

Moreover, in the second embodiment, the Si film 20 is formed on the SiGe film 11 formed in the channel region. The surface of the Si film 20 is nitrided to form the Si nitrogen-containing film 21. Thereafter, the gate insulating film 16a composed of the silicon oxide film 13 and the high-k film 15 is formed on the Si nitrogen-containing film 21 in the thick-film region.

As described above, in the thick-film region, the Si film 20 is formed on the SiGe film 11, and the Si nitrogen-containing film 21 is then formed on the Si film 20. Thus, the amount of Ge in the Si nitrogen-containing film 21 is smaller than that in the SiGe nitrogen-containing film 12 in the first embodiment. This further reduces the diffusion of Ge through the silicon oxide film 13. Therefore, the interface characteristics and reliability can further be inhibited from being degraded.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device comprising a first region including a first semiconductor element and a second region including a second semiconductor element different from the first semiconductor element, the method comprising:
forming a silicon germanium film on a surface of a semiconductor substrate in the first region and the second region;
nitriding the surface of the silicon germanium film at least in the first region;
forming a first insulating film mainly comprising silicon and oxygen, on the silicon germanium film in the first region and the second region;
removing the first insulating film in the second region; and
forming a second insulating film mainly comprising metal and oxygen, on a nitrided silicon germanium film in the second region.

2. The method according to claim 1, wherein the nitriding process is executed such that the surface of the silicon germanium film contains at least 1×10¹⁴ atoms/cm² of nitrogen.

3. The method according to claim 1, wherein the nitriding process is executed by plasma nitriding.

4. The method according to claim 1, wherein the nitriding process is executed by thermal nitriding using gaseous NH₃, NO, or N₂O.

5. The method according to claim 1, wherein the nitrided surface of the silicon germanium film contains oxygen.

6. The method according to claim 1, wherein the first region is a peripheral circuit region, and the second region is a core circuit region.

7. The method according to claim 1, wherein the first insulating film is a silicon oxide film or a silicon oxynitride film, and the second insulating film is an HfO₂ film, an HfON film, an HfSiON film, a ZrO₂ film, a ZrON film, or a ZrSiON film.

8. The method according to claim 1, wherein when the second insulating film is formed on the nitrided surface of the silicon germanium film in the second region, the second insulating film is also formed on the first insulating film in the first region.

9. The method according to claim 1, wherein the surface of the silicon germanium film in the second region is nitrided when the surface of the silicon germanium film in the first region is nitrided.

10. The method according to claim 1, wherein the surface of the silicon germanium film in the second region is nitrided after removing the first insulating film in the second region and before forming the second insulating film on the silicon germanium film in the second region.

11. The method according to claim 1, further comprising forming an oxide film on the silicon germanium film in the first region and the second region after forming the silicon germanium film on the surface of the semiconductor substrate in the first region and the second region and before nitriding the surface of the silicon germanium film in the first region and the second region, wherein the surface of the silicon germanium film in the first region and the second region is nitrided via the oxide film.

12. A method for manufacturing a semiconductor device comprising a first region including a first semiconductor element and a second region including a second semiconductor element different from the first semiconductor element, the method comprising:
forming a silicon germanium film on a surface of a semiconductor substrate in the first region and the second region;
forming a silicon film on the silicon germanium film in the first region and the second region;
nitriding a surface of the silicon film in the first region and the second region;
forming a first insulating film mainly comprising silicon and oxygen, on the nitrided silicon film in the first region and the second region;
removing the first insulating film in the second region; and
forming a second insulating film mainly comprising metal and oxygen, on the nitrided silicon film in the second region.

13. The method according to claim 12, wherein the nitriding process is executed such that the surface of the silicon film contains at least 1×10¹⁴ atoms/cm² of nitrogen.

14. The method according to claim 12, wherein the nitriding process is executed by plasma nitriding.

15. The method according to claim 12, wherein the nitriding process is executed by thermal nitriding using gaseous NH₃, NO, or N₂O.

16. The method according to claim 12, wherein the nitrided surface of the silicon film contains oxygen.

17. The method according to claim 12, wherein the first region is a peripheral circuit region, and the second region is a core circuit region.

18. The method according to claim 12, wherein the first insulating film is a silicon oxide film or a silicon oxynitride film, and the second insulating film is an HfO₂ film, an HfON film, an HfSiON film, a ZrO₂ film, a ZrON film, or a ZrSiON film.

19. The method according to claim 12, wherein when the second insulating film is formed on the nitrided surface of the silicon film in the second region, the second insulating film is also formed on the first insulating film in the first region.
